(19) United States
(12) Patent Application Publication
(10) Pub. No.: US 2015/0064908 A1
(43) Pub. Date: Mar. 5, 2015

(54) SUBSTRATE PROCESSING APPARATUS, METHOD FOR PROCESSING SUBSTRATE AND METHOD FOR MANUFACTURING SEMICONDUCTOR DEVICE

(71) Applicant: HITACHI KOKUSAI ELECTRIC INC., Tokyo (JP)

(72) Inventors: Atsushi Moriya, Toyama-shi (JP); Kiyohisa Ishibashi, Toyama-shi (JP)

(73) Assignee: HITACHI KOKUSAI ELECTRIC INC., Tokyo (JP)

(21) Appl. No.: 14/388,435

(22) PCT Filed: Mar. 22, 2013
(86) PCT No.: PCT/JP2013/058324

§ 371 Date: Sep. 26, 2014

(30) Foreign Application Priority Data
Feb. 15, 2013 (JP) 2013-027703

(51) Int. Cl. C23C 16/44; C23C 16/56; C23C 16/455; H01L 29/06; H01L 21/02; H01L 21/306; H01L 29/78; C23C 16/52; C23C 16/54

(52) U.S. Cl. CPC C23C 16/4405; C23C 16/4408; C23C 16/52; C23C 16/56; C23C 16/45502; C23C 16/54; H01L 21/02104; H01L 21/30604; H01L 29/78; H01L 29/0657; H01L 29/0603
USPC 438/694; 118/704; 118/702

(57) ABSTRACT

Provided is a substrate processing apparatus, including: a first gas supply system to supply raw material gas of a film being deposited in at least a portion of the surface of the substrate, and first etching gas which removes the deposited film, from a first gas supply nozzle to the processing chamber; a second gas supply system to supply second etching gas, which removes the deposited film, from a second gas supply nozzle to the processing chamber; and a control device to control the first and second gas supply systems such that the raw material gas is supplied from the first gas supply nozzle and the second etching gas is supplied from the second gas supply nozzle while the substrate is in the processing chamber, and the first etching gas is supplied from the first gas supply nozzle while the substrate is not in the processing chamber.

### BACKGROUND

1. Technical Field

The present invention relates to a substrate processing apparatus for use in a process of manufacturing a semiconductor device, a method for processing a substrate and a method for manufacturing a semiconductor device.

2. Related Art

Recently, in a metal oxide semiconductor field effect transistor (MOSFET), a technology called an elevated source/drain (or raised source/drain) for suppressing a short channel effect accompanied by a miniaturization of a gate length has attracted attention. This is also generally called a selective growth in a technology that epitaxially grows Si or SiGe in only a source/region region where Si is exposed and grows nothing in a region where other SiO₂ or SiN is exposed. Also, this is abbreviated to SEG, an acronym for Selective Epitaxial Growth.

As an apparatus for realizing the selective growth, there is a substrate processing apparatus disclosed in JP 2008-124181 A. In the substrate processing apparatus disclosed in JP 2008-124181 A, after monosilane (SiH₄) gas is supplied as source gas, Cl₂ gas is supplied as etching gas so as to remove Si nuclei attached to a surface of a SiO₂ or SiN film, and the raw material gas and the etching gas are alternately supplied. In this manner, the selective growth is realized. Also, a film is adhered to the inside of a nozzle by self-decomposition of the raw source gas and, after that, when the etching gas is made to flow into the same nozzle, particles are generated or the etching gas is consumed. Therefore, in the substrate processing apparatus disclosed in JP 2008-124181 A, the raw material gas and the etching gas are supplied from separate nozzles.

### SUMMARY

On the other hand, when the SiH₄ gas being the raw material gas is supplied to a reaction chamber of the substrate processing apparatus, a Si film is deposited in, for example, the inner wall of the reaction chamber and the nozzle through which the raw material gas flows, as well as the surface of the substrate. Therefore, the substrate processing apparatus needs to perform maintenance, such as cleaning of the inner wall of the reaction chamber or the nozzle, so as to remove the deposited Si film. As in the case of the substrate processing apparatus disclosed in JP 2008-124181 A, when the SiH₄ gas and the etching gas are supplied from separate nozzles to the reaction chamber, the adhesion of the Si film by the SiH₄ gas and the removal of the Si film by the etching gas are repeatedly performed on the inner wall of the reaction chamber or the like, whereas no etching gas is supplied to the nozzle through which the SiH₄ is supplied. Therefore, only the deposition of the Si film is continuously performed. Hence, the nozzle is easily clogged, and a maintenance cycle thereof is shortened as compared with the inner wall of the reaction chamber.

The present invention has been made in an effort to solve the above problems and is directed to provide a substrate processing apparatus or a method for manufacturing a semiconductor device, capable of extending a maintenance cycle.

In order to solve the above problem, an aspect of the present invention is a substrate processing apparatus including: a processing chamber configured to process a substrate; a first gas supply system configured to be able to supply raw material gas of a film, which is deposited in at least a portion of the surface of the substrate, and first etching gas, which removes the film deposited by the raw material gas, from a first gas supply nozzle to the processing chamber; a second gas supply system configured to be able to supply second etching gas, which removes the film deposited by the raw material gas, from a second gas supply nozzle to the processing chamber; and a control device configured to control the first gas supply system and the second gas supply system such that the raw material gas is supplied from the first gas supply nozzle and the second etching gas is supplied from the second gas supply nozzle in a state in which the substrate has been carried into the processing chamber, and the first etching gas is supplied from the first gas supply nozzle in a state in which the substrate is not present within the processing chamber.

Also, another aspect of the present invention is a method for manufacturing a semiconductor device, including: carrying a substrate into a processing chamber; a depositing by supplying raw material gas from a first gas supply nozzle to the inside of the processing chamber, and forming a film in at least a portion of the surface of the substrate; etching by supplying first etching gas from a second gas supply nozzle different from the first gas supply nozzle to the inside of the processing chamber, and removing the film deposited in the depositing; selectively forming a film with a predetermined film thickness in at least a portion of the surface of the substrate; carrying out the processed substrate from the processing chamber; and nozzle etching by supplying second etching gas from the first gas supply nozzle to the processing chamber and etching the film deposited in an inner wall of at least the first gas supply nozzle in a state in which the substrate is not present within the processing chamber.

According to the present invention, a maintenance cycle can be extended.

### BRIEF DESCRIPTION OF DRAWINGS

FIG. 1 is a schematic diagram illustrating a configuration of a substrate processing apparatus according to an embodiment of the present invention;

FIG. 2 is a longitudinal sectional view illustrating a configuration of a processing furnace of the substrate processing apparatus according to an embodiment of the present invention;

FIG. 3 is a diagram illustrating a configuration of a gas supply system of the substrate processing apparatus according to an embodiment of the present invention;

FIG. 4 is a process explanatory diagram illustrating a specific operation flow of a selective epitaxial growth of a Si film by using the substrate processing apparatus according to an embodiment of the present invention;

FIG. 5 is a process explanatory diagram illustrating a specific operation flow of a selective epitaxial growth of a Si film by using a substrate processing apparatus according to another embodiment of the present invention; and

FIG. 6 is a diagram illustrating a configuration of a gas supply system of the substrate processing apparatus according to another embodiment of the present invention.

### DETAILED DESCRIPTION

### First Embodiment

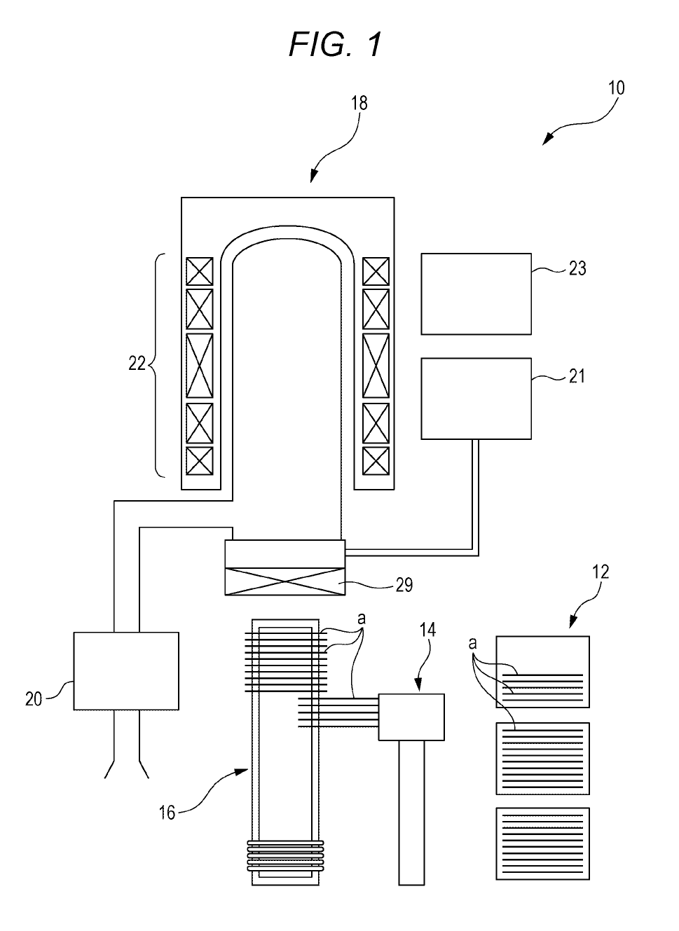

Hereinafter, an embodiment of the present invention will be described with reference to the drawings. FIG. 1 illustrates an overview of a substrate processing apparatus 10 according to an embodiment of the present invention. The substrate processing apparatus 10 is a so-called hot-wall type vertical low-pressure CVD apparatus. As illustrated in FIG. 1, a wafer (Si substrate) a carried by a wafer cassette 12 is transferred from the wafer cassette 12 to a boat 16 by a transfer machine 14. The transfer to the boat 16 is performed in a standby chamber. When the boat 16 is present in the standby chamber, the processing chamber is airtightly kept by a furnace throat gate valve 29. When the boat 16 completes the transfer of all wafers a, the furnace throat gate valve 29 is moved to open a furnace throat, and the boat 16 is inserted into the processing furnace 18. The inside of the processing furnace 18 is decompressed by a vacuum exhaust system 20. The inside of the processing furnace 18 is heated to a desired temperature by a heater 22. When the temperature is stabilized, raw material gas and etching gas are alternately supplied from a gas supply unit 21, and Si, SiGe, or the like is selectively epitaxially grown on the wafer a. Incidentally, a control system 23 controls the insertion of the boat 16 into the processing furnace 18 and the rotation of the boat 16, the exhaust in the vacuum exhaust system 20, the supply of gas from the gas supply unit 21, the heating by the heater 22, and the like.

As the raw material gas for the selective epitaxial growth of Si or SiGe, Si-containing gas, such as SiH₄, Si₂H₆, or SiH₂Cl₂, is used. In the case of SiGe, Ge-containing gas, such as GeH₄ or GeCl₄, is further added. In a CVD reaction, when the raw material gas is introduced, a growth on Si is immediately started, whereas a growth delay called a latency period occurs on an insulating film of SiO₂ or SiN. During the latency period, the growth of Si or SiGe on only Si is a selective growth. During the selective growth, the formation of Si nuclei (formation of a discontinuous Si film) occurs on the insulating film of SiO₂ or SiN, and the selectivity is damaged. Therefore, after the supply of the raw material gas, the Si nuclei (Si film) formed on the insulating film of SiO₂ or SiN are removed by supplying the etching gas. The selective epitaxial growth is performed by repeating the above process.

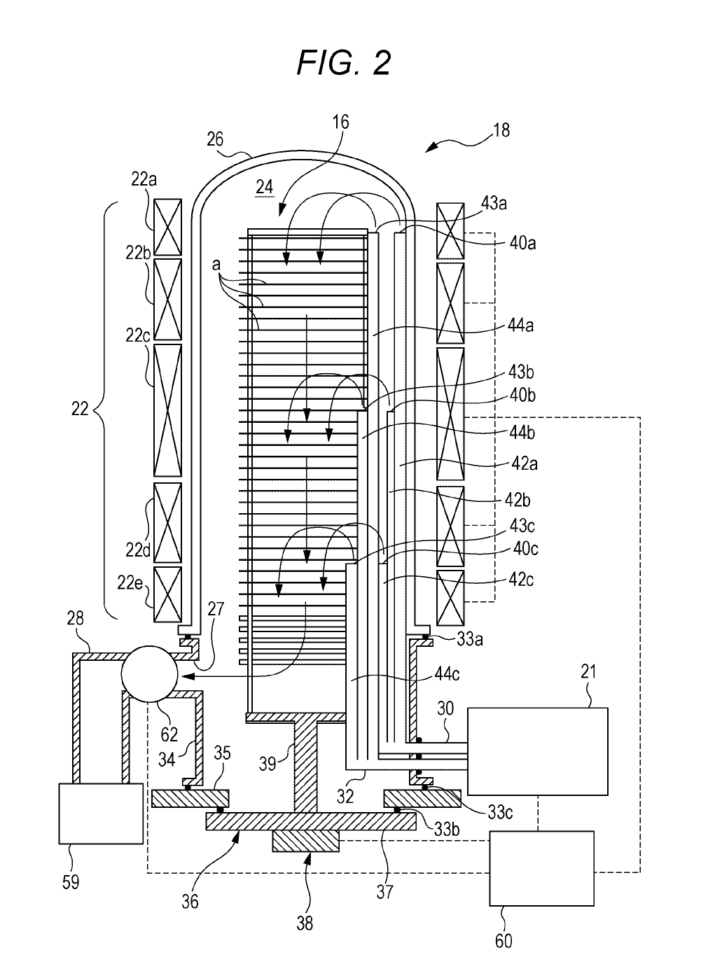

Next, the configuration after the insertion of the boat 16 into the processing furnace 18, which is used in the substrate processing apparatus 10 according to the embodiment of the present invention, will be described in detail with reference to the drawings. FIG. 2 is a longitudinal sectional view illustrating a schematic configuration of the processing furnace 18 after the insertion of the boat 16 according to an embodiment of the present invention. As illustrated in FIG. 2, the processing furnace 18 includes a reaction tube 26 that forms a processing chamber 24 and is made of, for example, an outer tube. A gas exhaust pipe 28, a first gas supply system 30, and a second gas supply system 32 are provided under the reaction tube 26. The first gas supply system 30 exhaust gas from an exhaust port 27. The first gas supply system 30 supplies the raw material gas to the inside of the processing chamber 24. The second gas supply system 32 supplies the etching gas to the inside of the processing chamber 24. The processing furnace 18 includes a manifold 34, a seal cap 36, the boat 16, a rotation mechanism 38, and a heater (heating member) 22. The manifold 34 is connected to the processing chamber 24 through an O-ring 33a. The seal cap 36 closes a lower portion of the manifold 34 seals the processing chamber 24 through O-rings 33b and 33c. The boat 16 serves as a wafer holder (substrate support member) that holds (supports) the wafers (Si substrates) a in multiple stages. The rotation mechanism 38 rotates the boat 16 at a predetermined rotating speed. The heater (heating member) 22 is made of a heater wire (not illustrated) and a heat insulation member (not illustrated) and heats the wafers a.

The reaction tube 26 is made of a heat resistant material, such as quartz (SiO₂) or silicon carbide (SiC), and is formed to have a cylindrical shape with a closed upper end and an opened lower end. The manifold 34 is made of, for example, stainless steel, and is formed to have a cylindrical shape with an opened upper end and an opened lower end. The upper end of the manifold 34 is engaged with the reaction tube 26 through the O-ring 33a. The seal cap 36 is made of, for example, stainless steel, and is formed by a ring-shaped part 35 and a disk-shaped part 37. The seal cap 36 closes the lower end of the manifold 34 through the O-rings 33b and 33c. Also, the boat 16 is made of a heat insulation material, such as quartz or silicon carbide, and is configured to hold the plurality of wafers a in a horizontal posture and in multiple stages arrange in such a state that the centers thereof are aligned. The rotation mechanism 38 of the boat 16 is configured such that a rotational shaft 39 passes through the seal cap 36 and is connected to the boat 16 to rotate the boat 16, which in turn rotates the wafer a.

Also, the heater 22 is divided into five regions, namely, an upper heater 22A, a central upper heater 22B, a central heater 22C, a central lower heater 22D, and a lower heater 22E, each of which has a cylindrical shape.

The processing furnace 18 includes a first gas supply system 30, in which three first gas supply nozzles 42a, 42b and 42c having first gas supply ports 40a, 40b and 40c with different heights are disposed. The processing furnace 18 also includes a second gas supply system 32, in which, aside from the first gas supply nozzles 42a, 42b and 42c, three second gas supply nozzles 44a, 44b and 44c having second gas supply ports 43a, 43b and 43c with different heights are disposed to constitute a second gas supply system 32. The first gas supply system and the second gas supply system are connected to the gas supply unit 21.

In the configuration of the processing furnace 18, the raw material gas (for example, SiH₄ gas) is supplied to three portions, namely, the upper portion, the central portion, and the lower portion of the boat 16, by the first gas supply nozzles 42a, 42b and 42c of the first gas supply system 30, and the etching gas (for example, Cl₂ gas) is supplied to three portions, namely, the upper portion, the central portion, and the lower portion of the boat 16 by the second gas supply nozzles 44a, 44b and 44c of the second gas supply system 32. Also, while the raw material gas is being supplied from the first gas supply system 30, the second gas supply system 32 is supplied with purge gas (for example, H₂ gas). While the etching gas is being supplied from the second gas supply system 32, the purge gas is supplied from the first gas supply system 30. Therefore, it is possible to prevent the gas of the other side from flowing back into the nozzle. Also, the atmosphere inside the processing chamber 24 is exhausted from the gas exhaust pipe 28 serving as an exhaust system. The gas exhaust pipe 28 is connected to an exhaust unit (for example, exhaust pump 59). The gas exhaust pipe 28 is provided under the processing chamber 24. As illustrated in FIG. 2, the gas ejected from the gas supply nozzles 42 and 44 flows from top to bottom. Since the gas flows from top to bottom, it can be configured such that the gas having passed through the lower portion of the processing chamber 24, to which a by-product is easily adhered due to a relatively low temperature, does not contact the substrate, and it can be expected to improve the film quality.

Furthermore, the substrate processing apparatus 10 includes a control device 60 that is electrically connected to the gas supply unit 21, the heater 22, and the vacuum pump 59 to control the respective operations thereof.

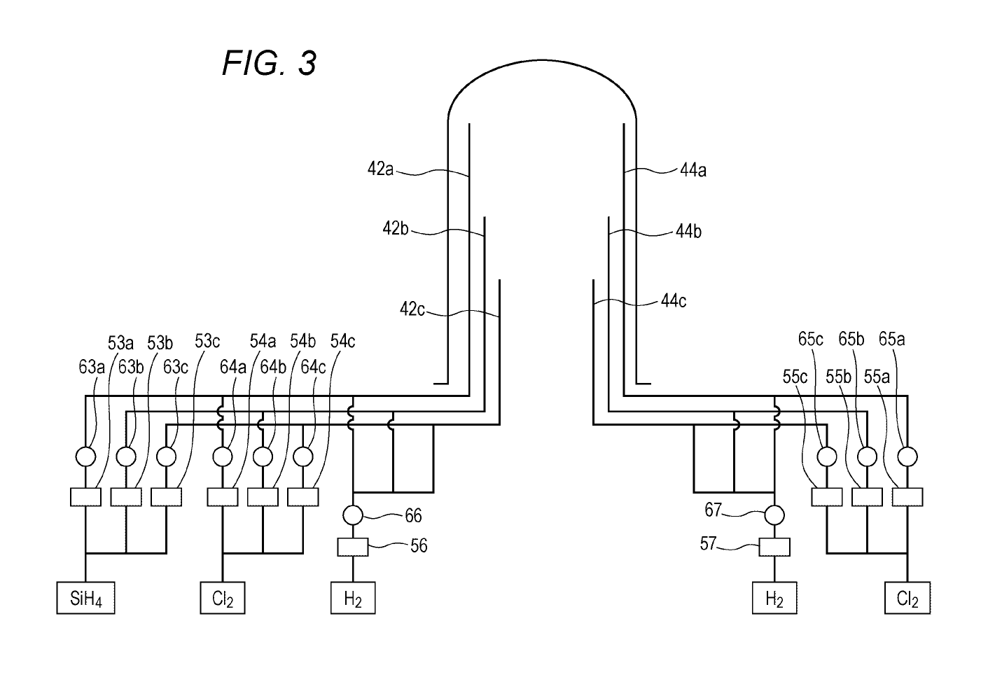

Next, the first gas supply system 30, the second gas supply system 32, and a gas supply unit 45 will be described with reference to FIG. 3. In FIG. 3, necessary parts are extracted for simplicity of description.

The first gas supply nozzles 42a, 42b and 42c included in the first gas supply system 30 are connected to a SiH₄ supply source being a raw material gas supply source through first mass flow controllers (hereinafter, referred to as “MFCs”) 53a, 53b and 53c as gas flow rate control units and first valves 63a, 63b and 63c, respectively. Also, the first gas supply nozzles 42a, 42b and 42c are connected to a Cl₂ supply source being an etching gas supply source through second MFCs 54a, 54b and 54c as second gas flow rate control units and second valves 64a, 64b and 64c, respectively. Furthermore, each of the first gas supply nozzles 42a, 42b and 42c is connected to an H₂ supply source being a purge gas supply source through a fourth MFC 56 and a fourth valve 66.

The second gas supply nozzles 44a, 44b and 44c included in the second gas supply system 32 are connected to a Cl₂ supply source being an etching gas supply source through third MFCs 55a, 55b and 55c as gas flow rate control units and third valves 65a, 65b and 65c, respectively. Also, each of the second gas supply nozzles 44a, 44b and 44c is connected to an H₂ supply source being a purge gas supply source through a fifth MFC 57 and a fifth valve 67.

Herein, in the present embodiment, the first gas supply system 30 and the first gas supply nozzles 42a, 42b and 42c, which supply the raw material gas to the inside of the processing chamber 24, are separated from the second gas supply system 32 and the second gas supply nozzles 44a, 44b and 44c, which supply the etching gas to the inside of the processing chamber 24. Since the raw material gas and the etching gas are supplied from separate nozzles, supply amounts of the raw material gas and the etching gas can be independently adjusted.

Also, in a case where the raw material gas and the etching gas are supplied from the same nozzle, a film is adhered to the inside of the nozzle by the self-decomposition of the raw material gas, and when the etching gas is made to flow therethrough, particles are generated or the etching gas is consumed. In contrast, in the present embodiment, since the raw material gas and the etching gas are supplied from separate nozzles, it is possible to avoid generating the particles from the nozzle. Also, since no film is adhered to the inner walls of the second gas supply nozzles 44a, 44b and 44c through which the etching gas is supplied, no etching gas is consumed in the second gas supply nozzles 44a, 44b and 44c and a more excellent etching characteristic can be obtained. Thus, it is possible to secure a stable etching rate with respect to the wafer a, regardless of the states of the inner walls of the first gas supply nozzles 42a, 42b and 42c and the second gas supply nozzles 44a, 44b and 44c.

Furthermore, the substrate processing apparatus is configured such that the etching gas can be also supplied from the first gas supply nozzles 42a, 42b and 42c. As described above, in the selective growth process, it is preferable to independently supply the raw material gas and the etching gas. In this regard, it is unnecessary to supply the etching gas to the first gas supply nozzles 42a, 42b and 42c through which the raw material gas is supplied. However, in the selective growth process, since the first gas supply nozzles 42a, 42b and 42c are supplied with the raw material gas but are not supplied with the etching gas, the deposition of the Si film may be progressed and thus the nozzle may be clogged. Therefore, as in the present embodiment, the substrate processing apparatus is configured such that the etching gas can also be supplied to the first gas supply nozzle through which the raw material gas is supplied, thereby making it possible to remove the Si film deposited on the inner wall of the first gas supply nozzle.

Furthermore, since a plurality of nozzles with different heights is provided with respect to each of the raw material gas and the etching gas, the adjustment can be performed by an intermediate supply of gas between the upper portion and the lower portion of the processing furnace 18, and it is possible to suppress the growth rate from being reduced as much as the exhaust side (lower portion inside the processing furnace 18) due to the consumption of the reaction gas. In particular, in the present embodiment, the first MFCs 53a, 53b and 53c and the first valves 63a, 63b and 63c are provided with respect to the first gas supply nozzles 42a, 42b and 42c, respectively. Also, the third MFCs 55a, 55b and 55c and the third valves 65a, 65b and 65c are provided with respect to the second gas supply nozzles 44a, 44b and 44c, respectively. By providing the valves or the MFCs with respect to the gas supply nozzles as described above, it is possible to adjust the flow rate of the gas supplied from each of the respective gas supply ports, and it is possible to further reduce the variation in the film thickness due to the difference in the height position of the wafer a.

Furthermore, in the present embodiment, the fourth MFC 56 and the fourth valve 66, which are provided with respect to the purge gas supply source, are shared by the three first gas supply nozzles 42a, 42b and 42c with different heights. Similarly, the fifth MFC 57 and the fifth valve 67, which are provided with respect to the purge gas supply source, are shared by the three second gas supply nozzles 44a, 44b and 44c with different heights. Since the purge gas is not gas that directly contributes to film formation, it is unnecessary to change the flow rate or the like at the height position, and it is possible to suppress the increase in the number of components by sharing some components. Incidentally, with respect to the purge gas, the increase in the number of components also occurs. It is obvious that independent MFCs or valves may be provided with respect to nozzles with different heights.

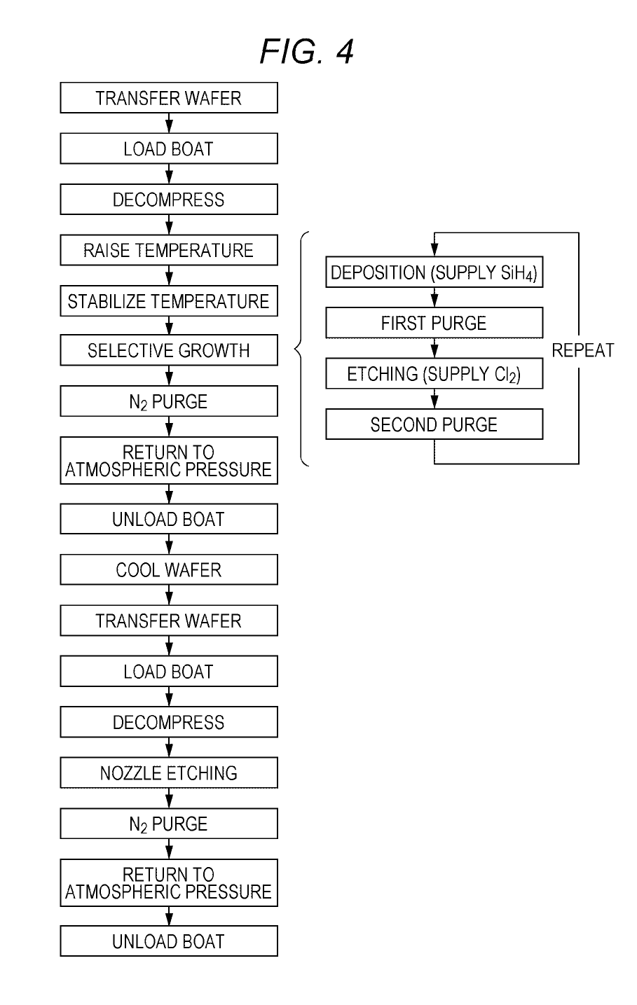

Next, an example of a substrate processing by the substrate processing apparatus 10 according to an embodiment of the present invention will be described with reference to FIG. 4. First, the wafer a, which is accommodated in the wafer cassette 12, is transferred to the boat 16 serving as the substrate holding unit by using the transfer machine 14 or the like (wafer transfer process). Incidentally, the wafer a has a surface to which Si is exposed, and a surface covered with an insulating film (SiN or SiO₂). Subsequently, the furnace throat gate valve 29 is moved to open the furnace throat, and the boat 16 holding unprocessed wafers a is inserted into the processing chamber 24 by driving an elevating motor (not illustrated) (boat loading process). Subsequently, the exhaust valve 62 is opened in response to a command from the control device 60, the atmosphere inside the processing chamber 24 is exhausted, and the inside of the processing chamber 24 is decompressed (decompression process). The heater 22 is controlled by the control device 60 to raise the temperature of the processing chamber 24 such that the temperature inside the processing chamber 24 and, therefore, the temperature of the wafer a become desired temperatures (temperature raising process), and raised temperatures are maintained until they are stabilized (temperature stabilizing process).

Subsequently, the selective growth process is performed on the wafer a. First, the rotation mechanism 38 is driven by a command from the control device 60 to rotate the boat 16 at a predetermined rotating speed. After the first MFCs 53a, 53b and 53c are adjusted in response to the command from the control device 60, the first valves 63a, 63b and 63c are opened, the raw material gas (SiH₄) starts being supplied from the first gas supply ports 40a, 40b and 40c to the processing chamber 24 through the first gas supply nozzles 42a, 42b and 42c, and the Si film is deposited on the Si surface of the wafer a for a predetermined time (deposition process). While the raw material gas is being supplied to the processing chamber 24, the fifth MFC 57 and the fifth valve 67 are controlled in response to the command from the control device 60 to supply the purge gas to the second gas supply nozzles 44a, 44b and 44c and suppress the entry of the raw material gas into the second gas supply nozzles 44a, 44b and 44c. Also, in the deposition process, the inner walls of the first gas supply nozzles 42a, 42b and 42c and the inner wall of the reaction tube 26 are also exposed to the raw material gas as in the case of the wafer a, and therefore, the Si film is deposited thereon.

Subsequently, the first MFCs 53a, 53b and 53c and the first valves 63a, 63b and 63c are controlled in response to a command from the control device 60 to stop supplying the raw material gas to the processing chamber 24. Also, the fourth MFC 56 and the fourth valve 66 are controlled to start supplying the purge gas from the first gas supply ports 40a, 40b and 40c through the first gas supply nozzles 42a, 42b and 42c. At this time, similarly, the purge gas is also supplied from the second gas supply ports 43a, 43b and 43c, and the raw material gas (SiH₄) remaining in the processing chamber 24 is removed (first purge process).

Subsequently, the fifth MFC 57 and the fifth valve 67 are controlled in response to a command from the control device 60 to stop supplying the purge gas to the second gas supply nozzles 44a, 44b and 44c. After that, the third MFCs 55a, 55b and 55c and the third valves 65a, 65b and 65c are controlled to supply the etching gas from the second gas supply ports 43a, 43b and 43c to the processing chamber 24 through the second gas supply nozzles 44a, 44b and 44c. Therefore, the removal of the Si film formed on the insulating film is performed (etching process). While the etching gas is being supplied to the processing chamber 24, the fourth MFC 56 and the fourth valve 66 are controlled in response to a command from the control device 60 to supply the purge gas to the first gas supply nozzles 42a, 42b and 42c and suppress the entry of the etching gas into the first gas supply nozzles 42a, 42b and 42c. Also, with respect to a portion exposed to the etching gas, such as the inner wall of the reaction tube 26, the Si film formed in the deposition process is etched at the same time. On the other hand, since the etching gas is not entered into the first gas supply pipe, the Si film deposited in the first gas supply pipe is not etched.

Subsequently, the third MFCs 55a, 55b and 55c and the third valves 65a, 65b and 65c are controlled in response to a command from the control device 60 to stop supplying the etching gas to the processing chamber 24. Also, the fifth MFC 57 and the fifth valve 67 are controlled to start supplying the purge gas from the second gas supply ports 43a, 43b and 43c through the second gas supply nozzles 44a, 44b and 44c. At this time, similarly, the purge gas is also supplied from the first gas supply ports 40a, 40b and 40c, and the etching gas (Cl₂) remaining in the processing chamber 24 is removed (second purge process).

The above deposition process, the first purge process, the etching process, and the second purge process are repeatedly performed to selectively grow the Si film with a predetermined film thickness on only the Si surface of the wafer a (selective growth process). After that, inert gas (for example, nitrogen (N₂) gas) is supplied to the inside of the processing chamber 24, and the atmosphere inside the processing chamber 24 is replaced with the inert gas (N₂ purge process). The inside of the processing chamber 24 is returned to an atmospheric pressure (atmospheric pressure process). After the boat 16 holding the processed wafer a is carried out from the inside of the processing chamber 24 by driving the elevating motor (not illustrated), the furnace throat is opened by the furnace throat gate valve 29 (boat unloading process). After that, the processed wafer a is cooled in the standby chamber (not illustrated) (wafer cooling process). The wafer a, which is cooled to a predetermined temperature, is accommodated in the wafer cassette 12 by using the transfer machine 14 (wafer transfer process), and the processing of the wafer a is completed.

Subsequently, the furnace throat gate valve is moved and the boat 16 holding no wafers a is carried into the processing chamber 24 again by driving the elevating motor (boat loading process). The exhaust valve 62 is opened, the atmosphere inside the processing chamber 24 is exhausted, and the inside of the processing chamber 24 is decompressed (decompression process). After that, the second MFCs 54a, 54b and 54c and the second valves 64a, 64b and 64c are controlled in response to a command from the control device 60, and an etching gas (Cl₂) is supplied to the inside of the processing chamber 24 through the first gas supply nozzles 42a, 42b and 42c. Therefore, the Si films, which are deposited in the inner walls of the first gas supply nozzles 42a, 42b and 42c during the deposition process, are etched and removed (nozzle etching process). Also, in the nozzle etching process, since the etching gas is also supplied to the inside of the processing chamber 24, the Si film remaining in the reaction tube 26 or the boat 16 without being removed can be etched and removed by the etching gas which have been made to flow in the selective growth process.

After that, inert gas (for example, nitrogen (N₂) gas) is supplied to the inside of the processing chamber 24, and the atmosphere inside the processing chamber 24 is replaced with the inert gas (N₂ purge process). The inside of the processing chamber 24 is returned to an atmospheric pressure (atmospheric pressure process). The boat 16 is carried out from the inside of the processing chamber 24 by driving the elevating motor (not illustrated), and the furnace throat is opened by the furnace throat gate valve 29 (boat unloading process).

In the present embodiment, the second MFCs 54a, 54b and 54c and the second valves 64a, 64b and 64c are provided with respect to the first gas supply nozzles 42a, 42b and 42c, and the etching gas can be supplied at different flow rates with respect to the first gas supply nozzles. The first MFCs 53a, 53b and 53c or the first valves 63a, 63b and 63c are provided with respect to the first gas supply nozzles 42a, 42b and 42c, respectively. In order to suppress a difference of a film thickness according to the height of the wafer a, an appropriate amount of the raw material gas is made to flow, and Si films each having a different thickness are deposited in the first gas supply nozzles 42a, 42b and 42c. As in the present embodiment, the configuration in which etching gas is made to flow through the first gas supply nozzles 42a, 42b and 42c at different flow rates allows etching gas to be supplied to the first gas supply nozzles 42a, 42b and 42c as appropriate cleaning gas, thereby suppressing the excessive supply of cleaning gas.

Therefore, in the nozzle etching process, the etching gas may be supplied from the second gas supply nozzles 44a, 44b and 44c, as well as the first gas supply nozzles 42a, 42b and 42c. Therefore, in addition to the cleaning of the inner walls of the first gas supply nozzles, the Si films formed in the reaction tube 26 or the boat 16 can be surely removed. However, in the selective growth of the present embodiment, since the etching gas is supplied to the inside of the processing chamber 24 during the selective growth process, Si nuclei are removed from the inner wall of the reaction tube 26 or the boat 16 in the etching process even though the Si nuclei are formed in the deposition process. Accordingly, even though the deposition of the Si film occurs, it is considered that the deposition of the Si film is small. Therefore, it is preferable that the excessive supply of the cleaning gas can be suppressed by supplying no etching gas from the second gas supply nozzles 44a, 44b and 44c and supplying the etching gas from only the first gas supply nozzles 42a, 42b and 42c.

Also, the nozzle etching process may be performed once when the selective growth process is performed multiple times. In this case, upon completion of the wafer transfer process of transferring the processed wafer a to the inside of the carrier, the unprocessed wafer a is transferred to the boat 16, thereby shortening the total time. However, it may be preferable to perform the nozzle etching process whenever the selective growth process is performed. In the general film forming apparatus, the inner wall of the reaction tube may be made opaque by coating, so as to prevent a transmission amount of radiation heat from the heater 22 from being changed according to an amount of film formation to the inner wall of the reaction tube. However, in the case of the selective growth, it is likely that adverse effects will appear. For example, in order to supply the etching gas to the processing chamber, the film is removed from the inner wall of the reaction tube and the coating film is partially removed. Therefore, in the case of the selective growth, it is considered that transmitting the radiation heat from the heater 22 by using the transparent reaction tube, as in the present embodiment, is more advantageous. That is, by performing the nozzle etching process whenever the selective growth process is performed, the Si film remaining in the inner wall of the reaction tube 26 can be removed, and the variation of the film formation condition can be suppressed by maintaining the reaction tube 26 in a transparent state.

### Second Embodiment

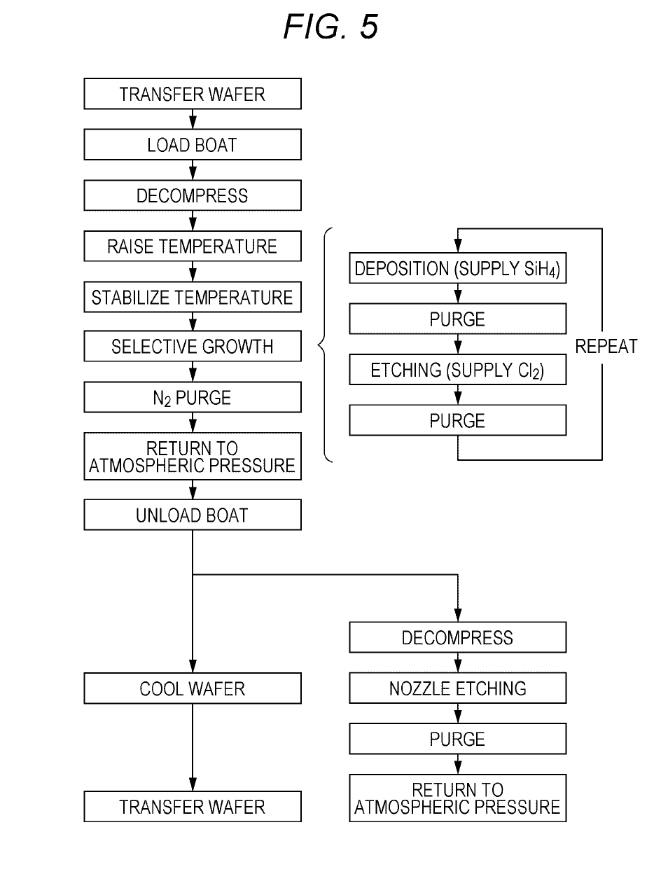

Next, a second embodiment will be described, focusing on differences from the first embodiment. FIG. 5 illustrates an example of substrate processing by the substrate processing apparatus 10 according to another embodiment of the present invention. In the present embodiment, processes from a wafer transfer process to a boat unloading process are similar to those of the first embodiment. However, unlike in the first embodiment where, after the wafer cooling process and the wafer transfer process are finished, the boat 16 holding no wafer a is carried in again and the nozzle etching process is performed. In contrast, the nozzle etching process in the present embodiment is performed in parallel to the wafer cooling process and the wafer transfer process.

Specifically, when the selective growth process is completed and the boat unloading process is performed, the furnace throat is opened by the furnace throat gate valve 29 and the processing chamber 24 is airtightly kept. In this state, the atmosphere inside the processing chamber 24 is exhausted by opening the exhaust valve 62, and the inside of the processing chamber 24 is decompressed (decompression process). After that, the second MFCs 54a, 54b and 54c and the second valves 64a, 64b and 64c are controlled in response to a command from the control device 60, and an etching gas (Cl₂) is supplied to the inside of the processing chamber 24 through the first gas supply nozzles 42a, 42b and 42c. Therefore, the Si films, which are deposited in the inner walls of the first gas supply nozzles 42a, 42b and 42c during the deposition process, are etched and removed. At the same time, since the etching gas is also supplied to the inside of the processing chamber 24, the Si film deposited in the inner wall of the reaction tube 26 is also etched and removed (nozzle etching process). After that, inert gas (for example, nitrogen (N₂) gas) is supplied to the inside of the processing chamber 24, and the atmosphere inside the processing chamber 24 is replaced with the inert gas (N₂ purge process), and the inside of the processing chamber 24 is returned to an atmospheric pressure (atmospheric pressure process). Also, in parallel to these processes, the processed wafer a is cooled in the standby chamber (not illustrated) (wafer cooling process). The wafer a, which is cooled to a predetermined temperature, is accommodated in the wafer cassette 12 by using the transfer machine 14 (wafer transfer process), and the processing of the wafer a is completed.

As described above, in the present embodiment, since the nozzle etching process is performed in parallel to the wafer cooling process and the wafer transfer process, the total processing time can be shortened as compared with the first embodiment.

Also, in the present embodiment, since the boat 16 is located outside the processing chamber 24 at the time of the nozzle etching process and the Si film deposited in the boat 16 is not etched, it is necessary to perform the removal for maintenance and the wafer cleaning, as needed, after the selective growth process is performed multiple times. However, as compared with the first embodiment, since the total processing time can be shortened, the total time can be shortened even considering the maintenance time of the boat 16.

Also, in the present embodiment, as in the first embodiment, the nozzle etching process may be performed once when the selective growth process is performed multiple times. The nozzle etching process may be performed whenever the selective growth process is performed. In particular, in the present embodiment, the nozzle cleaning is achieved during the cooling of the wafer by performing the nozzle etching process whenever the selective growth is performed, thereby shortening the time required for the nozzle etching process.

When assuming that 10 hours are required for one cycle of film formation and the nozzle etching time required for the one cycle of film forming process is 1 hour, the maintenance time in a case where the nozzle etching is performed every 10th cycle of film forming process will be compared with the maintenance time in a case where the nozzle etching is performed at the time of the cooling of the wafer as in the present embodiment. In the case where the nozzle etching is performed every 10th cycle of film forming process, the film formation processing time is 100 hours and 10 hours are taken for the nozzle etching. Therefore, the total maintenance time is 110 hours. In contrast, in the case where the nozzle etching is performed at the time of the cooling of the wafer as in the present embodiment, the maintenance time is 100 hours because the nozzle etching is performed during the film forming process. Therefore, it is possible to improve the productivity of 10% or more.

Also, in the present embodiment, since the boat 16 is located outside the processing chamber 24 at the time of the nozzle etching process, the heat insulation plate (not illustrated) for thermally insulating the lower furnace throat provided in the seal cap 36 moves downward from the processing chamber together with the boat 16, resulting in a state in which the heat insulation plate is not present in the furnace throat plate. Therefore, the temperature inside the furnace at the time of the nozzle etching process is controlled to be lower than the temperature inside the furnace at the time of the selective growth process, thereby avoiding heat flow to the furnace throat and preventing the degradation of members (not illustrated) outside the processing chamber in the vicinity of the furnace throat.

Furthermore, in the present embodiment, since the temperature inside the furnace cannot be raised at the time of the nozzle etching process, it is more preferable to perform the nozzle etching process with kinds of etching gas capable of maintaining an etching rate even at a lower temperature, such as Cl₂, than an etching gas having a low reactivity.

### Third Embodiment

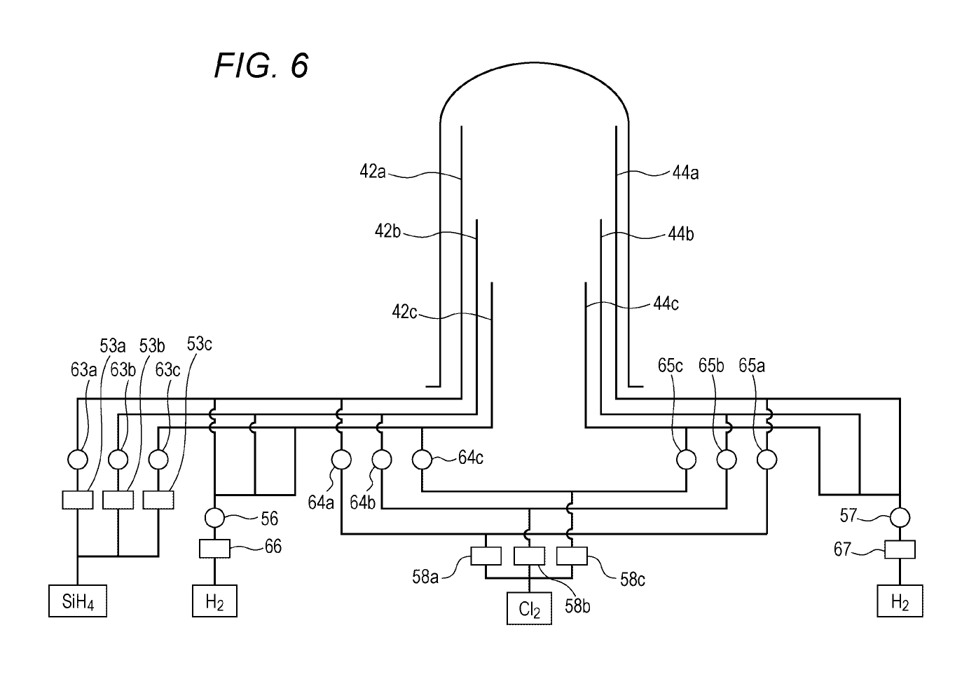

Next, a third embodiment will be described, focusing on differences from the first embodiment. FIG. 6 illustrates a schematic diagram of a gas supply system according to a third embodiment. In the first embodiment illustrated in FIG. 3, the MFCs for the etching gas are provided with respect to the first gas supply nozzles 42a, 42b and 42c and the second gas supply nozzles 44a, 44b and 44c. However, in the third embodiment illustrated in FIG. 6, the MFCs are shared with respect to the first gas supply nozzles and the second gas supply nozzles, of which the gas supply ports have the same height.

Specifically, the first gas supply nozzle 42a and the second gas supply nozzle 44a are respectively connected through a second valve 64a and a third valve 65a to a sixth MFC 58a, which is common thereto. Also, similarly, the remaining first gas supply nozzles 42b and 42c and the remaining second gas supply nozzles 44b and 44c share sixth MFCs 58b and 58c. Due to the above configuration, the etching gas cannot be simultaneously supplied from both of the first gas supply nozzles and the second gas supply nozzles, but the number of the MFCs can be reduced. Also, the control device 60 performs control such that the second valve 64a and the third valve 65a are not simultaneously opened.

Also, in the substrate processing apparatus 10 of the present embodiment, the substrate processing flows according to both of the first embodiment and the second embodiment can be realized. That is, in the first embodiment and the second embodiment, the etching gas need not be simultaneously supplied from both of the first gas supply nozzles and the second gas supply nozzles, and it is only necessary to control the second valves 64a, 64b and 64c and the third valves 65a, 65b and 65c such that the etching gas is supplied from the second gas supply nozzles in the etching process of the selective growth process and the etching gas is supplied from the first gas supply nozzles in the nozzle etching process.

Although the present invention has been described with reference to the embodiments, various modifications or appropriate combinations of the respective embodiments can be made without departing from the scope of the present invention. For example, in the above-descried embodiments, the selective growth of the Si film has been exemplified, but the present invention is not limited thereto. The present invention can be applied to a technology for forming a film on a wafer a by supplying raw material gas and etching gas from independent gas supply nozzles, for example, a selective growth of a SiGe film. Also, in the case of the selective growth of the SiGe film, it is only necessary to supply Si-containing gas (for example, SiH₄) and Ge-containing gas (for example, GeH₄) as raw material gas from the first gas supply nozzles or independent gas supply nozzles.

Also, the substrate processing apparatus in the embodiments is configured to supply the raw material gas and the etching gas from a plurality of supply nozzles, of which gas supply ports have different height positions. However, the raw material gas and the etching gas may be supplied from one gas supply nozzle.

Also, the etching gas in the etching process of the selective growth process and the etching gas in the nozzle etching process have been described as the same gas (Cl₂ gas), but the etching gas and the nozzle etching gas may be different gases. However, the etching gases of the same kind are preferable in terms of cost reduction.

Also, the use of the Cl₂ gas as the etching gas has been described, but the etching gas is not limited thereto and may be HCl gas. However, when gas having a high reactivity, such as ClF₃, is used, metal pollution easily occurs. Therefore, it is preferable to react at a low temperature and use etching gas, such as Cl₂, which has a high reactivity.

Also, at the time of the etching process of the selective growth process, an object is to remove a film formed on an insulating film of SiO₂ or SiN. Since a selectively grown film formed on Si having a high etching rate can be removed, it is preferable to perform control such that the pressure inside the furnace becomes lower than the pressure inside the furnace during the nozzle etching so as to reduce the etching rate. In this regard, in order to shorten the processing time of the nozzle etching process, it is preferable to perform control such that the pressure inside the furnace at the time of the nozzle etching process becomes higher than the pressure inside the furnace at the time of the etching process of the selective growth process. For example, the film deposited in the inner wall of the nozzle can be efficiently removed by performing control such that the pressure inside the furnace at the time of the etching process of the selective growth process becomes 15 Pa and the pressure inside the furnace at the time of the nozzle etching process becomes 500 Pa.

Also, in all the above-described embodiments, the deposition thickness of the film deposited in the first gas supply nozzles is increased from downstream to upstream of the film-formation gas supply by pressure gradient inside the nozzles. In order to efficiently remove the thick film part, immediately after the start of the nozzle etching process, the etching gas having a high reactivity or a high concentration can be supplied, and the etching gas having a low reactivity or a low concentration can be supplied according to the passage of the etching time.

Also, in the case of the selective growth, it is considered that transmitting radiation heat from the heat by using the transparent reaction tube is more advantageous. Therefore, the etching can be performed at the time of the nozzle etching process, without worrying out the coating of the inner wall. The thickest film deposited in the inner wall upstream of the first gas supply nozzle can be removed through etching above the thickness formed on the substrate (over-etching) by increasing the flow rate of supplying the etching gas to the first gas supply nozzles at the time of the nozzle etching process or lengthening the etching gas supply time.

That is, it is preferable to perform control such that the etching gas flow rate at the nozzle etching process is increased and the etching time is lengthened, as compared with the etching gas flow rate or the etching time at the time of the etching process of the selective growth process. In particular, such a configuration is efficient in the second embodiment in which no heat insulation member is present at the furnace throat and the temperature around the furnace throat cannot be raised.

Also, in the respective embodiments, it is preferable that the respective processing conditions of the etching process of the selective growth process and the nozzle etching process are controlled as follows.

That is, at the etching process of the selective growth process, it is preferable to perform control such that the supply flow rate of the etching gas supplied from the etching gas nozzle becomes 5 to 100 sccm, the pressure inside the furnace becomes 1 to 100 Pa, and the temperature inside the furnace becomes 550 to 700° C. Furthermore, at the nozzle etching process, it is preferable to perform control such that the supply flow rate of the etching gas supplied from the raw material gas nozzle becomes 10 to 500 sccm, the pressure inside the furnace becomes 10 to 1,000 Pa, and the temperature inside the furnace becomes 500 to 800° C.

By the processing in the above conditions, the film formed in the insulating film of SiO₂ or SiN on the wafer can be removed at the time of the etching process of the selective growth process. In the nozzle etching process, the deposition film deposited inside the raw material gas nozzle can be removed.

The present invention has been described with reference to the embodiments, but main aspects of the present invention will be additionally stated.

### (Supplementary Note 1)

According to one aspect of the present invention, there is provided a substrate processing apparatus including: a processing chamber configured to process a substrate; a first gas supply system configured to supply raw material gas of a film, which is deposited in at least a portion of the surface of the substrate, and first etching gas, which removes the film deposited by the raw material gas, from a first gas supply nozzle to the processing chamber; a second gas supply system configured to be able to supply second etching gas, which removes the film deposited by the raw material gas, from a second gas supply nozzle to the processing chamber; and a control device configured to control the first gas supply system and the second gas supply system such that the raw material gas is supplied from the first gas supply nozzle and the second etching gas is supplied from the second gas supply nozzle in a state in which the substrate has been carried into the processing chamber, and the first etching gas is supplied from the first gas supply nozzle in a state in which the substrate is not present within the processing chamber.

### (Supplementary Note 2)

Also, in Supplementary Note 1, the first gas supply system is further configured to be able to supply purge gas from the first gas supply nozzle to the processing chamber, the second gas supply system is further configured to be able to supply purge gas from the second gas supply nozzle to the processing chamber, and the control device controls the first gas supply system and the second gas supply system such that in the state in which the substrate has been carried into the processing chamber, supplying the raw material gas to the processing chamber, removing the raw material gas inside the processing chamber by the purge gas, supplying the second etching gas, and removing the second etching gas inside the processing chamber by the purge gas are repeated.

### (Supplementary Note 3)

Also, in Supplementary Note 2, the control device controls the first gas supply system and the second gas supply system such that the purge gas is supplied into the processing chamber from both of the first gas supply nozzle and the second gas supply nozzle when the raw material gas inside the processing chamber is removed by the purge gas and when the second etching gas inside the processing chamber is removed by the purge gas.

### (Supplementary Note 4)

Also, in Supplementary Note 2 or 3, the control device controls the first gas supply system and the second gas supply system such that the purge gas is supplied from the second gas supply nozzle while the raw material gas is being supplied from the first gas supply nozzle to the processing chamber, and the purge gas is supplied from the first gas supply nozzle while the second etching gas is being supplied from the second gas supply nozzle to the processing chamber.

### (Supplementary Note 5)

Also, in any one of Supplementary Notes 1 to 4, the control device controls such that the second etching gas is not supplied from the second gas supply nozzle to the processing chamber while the first etching gas is being supplied from the first gas supply nozzle to the processing chamber.

### (Supplementary Note 6)

Also, in any one of Supplementary Notes 1 to 5, an etching gas supply source which supplies both of the first etching gas and the second etching gas is connected to a first valve and a second valve through a flow rate control unit commonly provided to the first gas supply system including the first valve provided between an etching gas supply source and the first gas supply nozzle and the second gas supply system including the second valve provided between the etching gas supply source and the second gas supply nozzle.

### (Supplementary Note 7)

Also, in any one of Supplementary Notes 1 to 6, the control device controls the first gas supply system and the second gas supply system such that a supply time to supply the first etching gas from the first gas supply nozzle in the state in which the substrate is not present within the processing chamber becomes longer than a supply time to supply the second etching gas from the second gas supply nozzle in the state in which the substrate has been carried into the processing chamber.

### (Supplementary Note 8)

Also, in any one of Supplementary Notes 1 to 7, the control device controls the first gas supply system and the second gas supply system such that a pressure inside the processing chamber, in the case of supplying the first etching gas from the first gas supply nozzle in the state in which the substrate is not present within the processing chamber, becomes higher than a pressure inside the processing chamber in the case of supplying the raw material gas from the first gas supply nozzle and supplying the second etching gas from the second gas supply nozzle in the state in which the substrate has been carried into the processing chamber.

### (Supplementary Note 9)

Also, in any one of Supplementary Notes 1 to 8, the substrate processing apparatus includes a heating member configured to heat the inside of the processing chamber, and the control device controls the heating member such that a temperature inside the processing chamber, in the case of supplying the first etching gas from the first gas supply nozzle in the state in which the substrate is not present within the processing chamber, becomes lower than a temperature inside the processing chamber in the case of supplying the raw material gas from the first gas supply nozzle and supplying the second etching gas from the second gas supply nozzle in the state in which the substrate has been carried into the processing chamber.

### (Supplementary Note 10)

Also, according to another aspect of the present invention, there is provided a method for manufacturing a semiconductor device, including: a carrying-in process of carrying a substrate into a processing chamber; a deposition process of supplying raw material gas from a first gas supply nozzle to the inside of the processing chamber, and forming a film in at least a portion of the surface of the substrate; an etching process of supplying first etching gas from a second gas supply nozzle different from the first gas supply nozzle to the inside of the processing chamber, and removing the film deposited in the deposition process; a selective growth process of selectively forming a film with a predetermined film thickness in at least a portion of the surface of the substrate; a carrying-out process of carrying out the processed substrate from the processing chamber; and a nozzle etching process of supplying second etching gas from the first gas supply nozzle and etching the film deposited in an inner wall of at least the first gas supply nozzle in a state in which the present is not present within the processing chamber.

### (Supplementary Note 11)

Also, in Supplementary Note 10, the selective growth process includes a first purge process of removing the raw material gas inside the processing chamber after the deposition process, and a second purge process of removing the first etching gas inside the processing chamber after the etching process, and the deposition process, the first purge process, the etching process, and the second purge process are repeated.

### (Supplementary Note 12)

In Supplementary Note 10 or 11, the substrate is carried into the processing chamber in a state in which the substrate is held by a substrate holder, and is carried out from the processing chamber in a state in which the substrate is held by the substrate holder, and the nozzle etching process is performed after the carrying-out process is performed, the substrate is removed from the substrate holder and the substrate holder is returned to the processing chamber.

### (Supplementary Note 13)

In Supplementary Note 7 or 8, the substrate is carried into the processing chamber in a state in which the substrate is held by a substrate holder, and is carried out from the processing chamber in a state in which the substrate is held by the substrate holder, and the nozzle etching process is performed in parallel to the substrate transfer process of taking out the substrate from the substrate holder after the carrying-out process.

### (Supplementary Note 14)

Also, according to another aspect of the present invention, there is provided a method for processing a substrate, including: a carrying-in process of carrying a substrate into a processing chamber; a deposition process of supplying raw material gas from a first gas supply nozzle to the inside of the processing chamber, and forming a film in at least a portion of the surface of the substrate; an etching process of supplying first etching gas from a second gas supply nozzle different from the first gas supply nozzle to the inside of the processing chamber, and removing the film deposited in the deposition process; a selective growth process of selectively forming a film with a predetermined film thickness in at least a portion of the surface of the substrate; a carrying-out process of carrying out the processed substrate from the processing chamber; and a nozzle etching process of supplying second etching gas from the first gas supply nozzle and etching the film deposited in an inner wall of at least the first gas supply nozzle in a state in which the present is not present within the processing chamber.

### (Supplementary Note 15)

Also, according to another aspect of the present invention, there is provided a method for manufacturing a substrate, including: a carrying-in process of carrying a substrate into a processing chamber; a deposition process of supplying raw material gas from a first gas supply nozzle to the inside of the processing chamber, and forming a film in at least a portion of the surface of the substrate; an etching process of supplying first etching gas from a second gas supply nozzle different from the first gas supply nozzle to the inside of the processing chamber, and removing the film deposited in the deposition process; a selective growth process of selectively forming a film with a predetermined film thickness in at least a portion of the surface of the substrate; a carrying-out process of carrying out the processed substrate from the processing chamber; and a nozzle etching process of supplying second etching gas from the first gas supply nozzle and etching the film deposited in an inner wall of at least the first gas supply nozzle in a state in which the present is not present within the processing chamber.

### FIG. 4

### TRANSFER WAFER

### LOAD BOAT

### DECOMPRESS

### RAISE TEMPERATURE

### STABILIZE TEMPERATURE

### SELECTIVE GROWTH

DEPOSITION (SUPPLY SiH₄)

FIRST PURGE

ETCHING (SUPPLY Cl₂)

SECOND PURGE

REPEAT

### N₂ PURGE

### RETURN TO ATMOSPHERIC PRESSURE

### UNLOAD BOAT

### COOL WAFER

### TRANSFER WAFER

### LOAD BOAT

### DECOMPRESS

### NOZZLE ETCHING

### N₂ PURGE

### RETURN TO ATMOSPHERIC PRESSURE

### UNLOAD BOAT

### FIG. 5

### TRANSFER WAFER

### LOAD BOAT

### DECOMPRESS

### RAISE TEMPERATURE

### STABILIZE TEMPERATURE

### SELECTIVE GROWTH

DEPOSITION (SUPPLY SiH₄)

PURGE

ETCHING (SUPPLY Cl₂)

PURGE

REPEAT

### N₂ PURGE

### RETURN TO ATMOSPHERIC PRESSURE

### UNLOAD BOAT

### COOL WAFER

### TRANSFER WAFER

### DECOMPRESS

### NOZZLE ETCHING

### N₂ PURGE

### PURGE

RETURN TO ATMOSPHERIC PRESSURE

What is claimed is:

1. A substrate processing apparatus comprising:
a processing chamber configured to process a substrate;
a first gas supply system configured to be able to supply raw material gas of a film, which is deposited in at least a portion of the surface of the substrate, and first etching gas, which removes the film deposited by the raw material gas, from a first gas supply nozzle to the processing chamber;
a second gas supply system configured to be able to supply second etching gas, which removes the film deposited by the raw material gas, from a second gas supply nozzle to the processing chamber; and
a control device configured to control the first gas supply system and the second gas supply system such that the raw material gas is supplied from the first gas supply nozzle and the second etching gas is supplied from the second gas supply nozzle in a state in which the substrate has been carried into the processing chamber, and such that the first etching gas is supplied from the first gas supply nozzle in a state in which the substrate is not present within the processing chamber.

2. The substrate processing apparatus according to claim 1, wherein
the first gas supply system is further configured to be able to supply purge gas from the first gas supply nozzle to the processing chamber,
the second gas supply system is further configured to be able to supply purge gas from the second gas supply nozzle to the processing chamber, and
the control device controls the first gas supply system and the second gas supply system such that in the state in which the substrate has been carried into the processing chamber, supplying the raw material gas to the processing chamber, removing the raw material gas inside the processing chamber by the purge gas, supplying the second etching gas, and removing the second etching gas inside the processing chamber by the purge gas are repeated.

3. The substrate processing apparatus according to claim 2, wherein the control device controls the first gas supply system and the second gas supply system such that the purge gas is supplied into the processing chamber from both of the first gas supply nozzle and the second gas supply nozzle when the raw material gas inside the processing chamber is removed by the purge gas and when the second etching gas inside the processing chamber is removed by the purge gas.

4. The substrate processing apparatus according to claim 2, the control device controls the first gas supply system and the second gas supply system such that the purge gas is supplied from the second gas supply nozzle while the raw material gas is being supplied from the first gas supply nozzle to the processing chamber, and the purge gas is supplied from the first gas supply nozzle while the second etching gas is being supplied from the second gas supply nozzle to the processing chamber.

5. The substrate processing apparatus according to claim 1, wherein the control device controls the second gas supply system such that the second etching gas is not supplied from the second gas supply nozzle to the processing chamber while the first etching gas is being supplied from the first gas supply nozzle to the processing chamber.

6. The substrate processing apparatus according to claim 1, wherein an etching gas supply source which supplies both of the first etching gas and the second etching gas is connected to a first valve and a second valve through a flow rate control unit commonly provided to the first gas supply system including the first valve provided between an etching gas supply source and the first gas supply nozzle and the second gas supply system including the second valve provided between the etching gas supply source and the second gas supply nozzle.

7. The substrate processing apparatus according to claim 1, wherein the control device controls the first gas supply system and the second gas supply system such that a supply time to supply the first etching gas from the first gas supply nozzle in the state in which the substrate is not present within the processing chamber becomes longer than a supply time to supply the second etching gas from the second gas supply nozzle in the state in which the substrate has been carried into the processing chamber.

8. The substrate processing apparatus according to claim 1, wherein the control device controls the first gas supply system and the second gas supply system such that a pressure inside the processing chamber, in the case of supplying the first etching gas from the first gas supply nozzle in the state in which the substrate is not present within the processing chamber, becomes higher than a pressure inside the processing chamber in the case of supplying the raw material gas from the first gas supply nozzle and supplying the second etching gas from the second gas supply nozzle in the state in which the substrate has been carried into the processing chamber.

9. The substrate processing apparatus according to claim 1, wherein the substrate processing apparatus comprises a heating member configured to heat the inside of the processing chamber, and
the control device controls the heating member such that a temperature inside the processing chamber, in the case of supplying the first etching gas from the first gas supply nozzle in the state in which the substrate is not present within the processing chamber, becomes lower than a temperature inside the processing chamber in the case of supplying the raw material gas from the first gas supply nozzle and supplying the second etching gas from the second gas supply nozzle in the state in which the substrate has been carried into the processing chamber.

10. A method for manufacturing a semiconductor device, comprising:
a carrying-in process of carrying a substrate into a processing chamber;
a depositing process of depositing by supplying raw material gas from a first gas supply nozzle to the inside of the processing chamber, and forming a film in at least a portion of a surface of the substrate;
an etching process of supplying first etching gas from a second gas supply nozzle different from the first gas supply nozzle to the inside of the processing chamber, and removing the film in the deposition process;
a selective growth process of selectively forming a film with a predetermined film thickness in at least a portion of the surface of the substrate;
a carrying-out process of carrying out the processed substrate from the processing chamber; and
a nozzle etching process of supplying second etching gas from the first gas supply nozzle to the processing chamber and etching the film deposited in an inner wall of at least the first gas supply nozzle in a state in which the substrate is not present within the processing chamber.

11. The method for manufacturing a semiconductor device according to claim 10, wherein the selective growth process includes a first purge process of removing the raw material gas inside the processing chamber after the deposition process, and a second purge process of removing the first etching gas inside the processing chamber after the etching process, and the deposition process, the first purge process, the etching process, and the second purge process are repeated.

12. The method for manufacturing a semiconductor device according to claim 10, wherein the substrate is carried into the processing chamber in a state in which the substrate is held by a substrate holder, and is carried out from the processing chamber in a state in which the substrate is held by the substrate holder, and, the nozzle etching process is performed after the carrying-out process is performed, the substrate is removed from the substrate holder and the substrate holder is returned to the processing chamber.

13. A method for processing a substrate, comprising:
a carrying-in process of carrying a substrate into a processing chamber;
a depositing process of depositing by supplying raw material gas from a first gas supply nozzle to the inside of the processing chamber, and forming a film in at least a portion of a surface of the substrate;
an etching process of supplying first etching gas from a second gas supply nozzle different from the first gas supply nozzle to the inside of the processing chamber, and removing the film in the deposition process;
a selective growth process of selectively forming a film with a predetermined film thickness in at least a portion of the surface of the substrate;
a carrying-out process of carrying out the processed substrate from the processing chamber; and
a nozzle etching process of supplying second etching gas from the first gas supply nozzle to the processing chamber and etching the film deposited in an inner wall of at least the first gas supply nozzle in a state in which the substrate is not present within the processing chamber.
